(19) United States
(12) Patent Application Publication
(10) Pub. No.: US 2014/0202986 A1
(43) Pub. Date: Jul. 24, 2014

(54) HIGH ASPECT RATIO PATTERNING USING NEAR-FIELD OPTICAL LITHOGRAPHY WITH TOP SURFACE IMAGING

(71) Applicants: Alfred Renaldo, San Jose, CA (US); Boris Kobrin, Dublin, CA (US)

(72) Inventors: Alfred Renaldo, San Jose, CA (US); Boris Kobrin, Dublin, CA (US)

(73) Assignee: Rolith, Inc., Pleasanton, CA (US)

(21) Appl. No.: 13/749,376

(22) Filed: Jan. 24, 2013

(51) Int. Cl. G03F 7/00

(52) U.S. Cl. CPC G03F 7/0002
USPC 216/41

(57) ABSTRACT

Rolling mask lithography may be performed to expose selected portions of a radiation sensitive layer to a radiation pattern that leaves selected portions of a top surface of the radiation sensitive layer resistant to development by a developer and non-selected portions susceptible to development by the developer. A structure of the selected portions is then rendered resistant to an etch process. The radiation sensitive layer is then flood exposed to a second radiation that leaves the radiation sensitive layer resistant to development by the developer. The radiation sensitive layer is then selectively etched using the etch-resistant selected portions as an etch mask.

### FIELD

Embodiments of the invention relate to patterning of substrates and more particularly patterning a substrate with rolling mask lithography.

### BACKGROUND

This section describes background subject matter related to the disclosed embodiments of the present invention. There is no intention, either express or implied, that the background art discussed in this section legally constitutes prior art.

Patterned substrates and structured coatings have attractive properties for a variety of applications, including architectural glass, information displays, solar panels, and more. For example, nanostructured coatings can provide desirable antireflection characteristics for architectural glass. Current methods of patterning substrates, include lithographic methods such as electron beam lithography, photolithography, interference lithography, imprint lithography and other methods. These methods generally involve forming a layer of radiation sensitive material on a surface of the substrate and exposing the material, or selected portions of the material to radiation. The radiation exposure changes the physical or chemical properties of the material in such a way that a pattern is transferred to the material in a process known as developing the resist. By way of example, in photolithography, a layer of radiation sensitive photoresist is exposed to radiation that is transmitted through some form of patterned mask. As a result of the mask, selected portions of the resist are exposed to the radiation and others are not.

Depending on the type of resist, the radiation exposure either cures the resist to make exposed portions resistant to removal or weakens the exposed portions making them susceptible to removal. The developing process removes the un-exposed (or exposed) portions of the resist to transfer the pattern to the resist. The pattern may have openings that allow a chemical or physical etch process to attack the underlying substrate and remove material from it.

One type of etch process is known as a dry etch process. In this type of etch process, reactive species are directed toward the substrate so that the etching preferentially takes place in one direction. Dry etch processes often use plasma to generate reactive ions that can be directed toward the substrate by an electric field.

It would be desirable to nanostructure many types of substrate materials with dry etching for applications in many present technologies and industries and for new technologies that are under development. By way of example and not by way of limitation, such nanostructuring could lead to improvements in efficiency in areas such as solar cells and LEDs, creating new advanced features in products such as glass for displays and architectural windows.

Nanostructured substrates may be fabricated using dry etching in conjunction with conventional lithographic patterning techniques, such as e-beam direct writing, Deep UV lithography, nanosphere lithography, nanoimprint lithography, near-filed phase shift lithography, and plasmonic lithography, for example. A drawback to such conventional lithographic patterning processes is that they are often too costly for practical use in the manufacture of patterned substrates or structured coatings in applications requiring larger areas, especially those having areas of 200 cm² or more. Some previous techniques for patterning large area substrates include Rolling Mask Lithography (RML), which is described in commonly-assigned U.S. patent application Ser. No. 12/384,219, filed Apr. 1, 2009, the entire contents of which are incorporated herein by reference.

Rolling mask lithography is essentially a “near-field” optical lithography, which can be implemented using soft phase masks or plasmonic masks. “Near-field” feature tends to limit the depth of structures that can be formed in a resist to relatively shallow depths. In order to get high aspect ratio nanostructures plasma etching techniques are used. Even with such etching techniques it is very hard to obtain deep structures due to a limited etch selectivity of soft resist materials. An additional metal or other “hard mask” may be used to allow deeper etching, but this adds complexity to the process.

It is within this context that a need for the present invention arises.

### INTRODUCTION

Aspects of the present disclosure pertain to methods and apparatus useful in patterning substrates with high aspect ratio features. By way of example and not by way of limitation, such substrates may be large area substrates, which may range in size from about 200 mm² to about 1,000,000 mm², or more. In some instances the substrate may be in the form of a sheet or film, which has a given width and an undefined length, which may be provided on a roll.

Generally, to overcome the drawbacks described above, one can implement a “top-surface-imaging” technique, which is known in the industry (for example, DESIRE, PRIME, SUPER, SAHR, others).

The DESIRE PROCESS is described, e.g., by F. Coopmans and G. Roland in Solid State Technology, 1987, vol. 30, No. 6, p 93, which is incorporated herein by reference.

The PRIME process is described, e.g., by C. Peirrat et al in in Journal of Vacuum Science and Technology B, 1989, vol. 7, p 1782, which is incorporated herein by reference.

The SUPER process is described, e.g., by C Mutsaers et al, in Journal of Microelectronic Engineering, 1990, Vol. 11, p. 497, which is incorporated herein by reference.

The SAHR process is described, e.g., by E. Pavlichek et al in in Journal of Vacuum Science and Technology B, 1990, vol. 8, p 1497, which is incorporated herein by reference.

As an example, in the DESIRE process a substrate can be coated with a traditional novolac/DNQ photoresist resist having a desired thickness. The thick resist can then be exposed using a “Rolling mask” lithography method. The resist may then be baked and then treated using silane chemistry in a process called “silylation”, which can be done in vapor treatment in vacuum. The silylation changes the resist structure only in selected areas since permeation in other areas is drastically diminished due to cross-linking. As the result of “silylation” process, the silane compound permeates into exposed regions and incorporates silicon into these regions. Silylated areas may be converted to glass areas. The resist can then be etched in oxygen-based plasma etching process using these glass areas as an etch mask. As the result high aspect ratio nanostructures may be formed in the resist. This process produces a negative tone high-aspect ratio images in resist.

Another embodiment using a 2-layer scheme, where first, one can deposit a polymer layer with required thickness (not necessarily photosensitive), bake it, and then overcoat it with a thin layer of photoresist. Then expose photoresist using “Rolling mask” lithography, develop the photoresist, bake it and then use the resulting patterned photoresist as a mask for oxygen-based etching of polymer.

And yet, another embodiment is to use so called “CARL” process, where first, a substrate is coated with a polymer layer of a required thickness, then it is baked and overcoated with a thin layer of photoresist. Next, the photoresist layer is exposed using “rolling mask” lithography, and developed. The photoresist may then be “silylated” while still in liquid (undeveloped) phase, and finally obtained such cross-liked silicon-rich areas that can be used as masks for oxygen-based plasma etching of the polymer.

By way of example, and not by way of limitation, the patterning technique used to pattern the radiation-sensitive material may make use of Near-Field UV photolithography, where the mask used to pattern the substrate is in contact or in very close proximity (in the evanescent field, less than 100 nm) from the substrate. The Near-Field photolithography may include a phase-shifting mask or surface plasmon technology. The Near-Field photolithography may use deep ultraviolet (DUV), e.g., 248 nm radiation. The Near-Field photolithography may also include chemically amplified resist processes as well as I-line (365 nm wavelength) processes.

According to an aspect of the present disclosure, the exposure apparatus may include a phase-shifting mask in the form of a UV-transparent rotatable mask having specific phase shifting relief on its outer surface. According to another aspect, the phase-shifting mask may be in the form of a transparent cylinder, which may have a nanopattern on its surface configured to act as a phase-shifting mask.

### BRIEF DESCRIPTION OF THE DRAWINGS

The teachings of the present invention can be readily understood by considering the following detailed description in conjunction with the accompanying drawings. It is to be appreciated that drawings are provided only when necessary to understand certain aspects of the present disclosure and that certain well known processes and apparatus are not illustrated herein in order not to obscure the inventive nature of the subject matter of the disclosure.

FIG. 1A shows a cross-sectional view of one embodiment of an apparatus 100 useful in patterning of large areas of substrate material in conjunction with aspects of the present disclosure.

FIG. 1B shows a top view of the apparatus and substrate illustrated in FIG. 1A.

FIG. 2 shows a cross-sectional view of another embodiment of an apparatus 200 useful in patterning of large areas of substrate material in conjunction with aspects of the present disclosure.

FIGS. 3A-3F are a sequence of cross-sectional diagrams illustrating forming a patterned structure on a substrate in accordance with an aspect of the present disclosure.

FIGS. 4A-4F are a sequence of cross-sectional diagrams illustrating an alternative method of forming a patterned structure on a substrate in accordance with an alternative aspect of the present disclosure.

FIGS. 5A-5F are a sequence of cross-sectional diagrams illustrating another alternative method of forming a patterned structure on a substrate in accordance with an alternative aspect of the present disclosure.

### DETAILED DESCRIPTION

As a preface to the detailed description, it should be noted that, as used in this specification and the appended claims, the singular forms “a”, “an”, and “the” include plural referents, unless the context clearly dictates otherwise.

When the word “about” is used herein, this is intended to mean that the nominal value presented is precise within ±10%. Furthermore, in the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Aspects of the present disclosure relate to methods and apparatus useful in the nanopatterning of large area substrates.

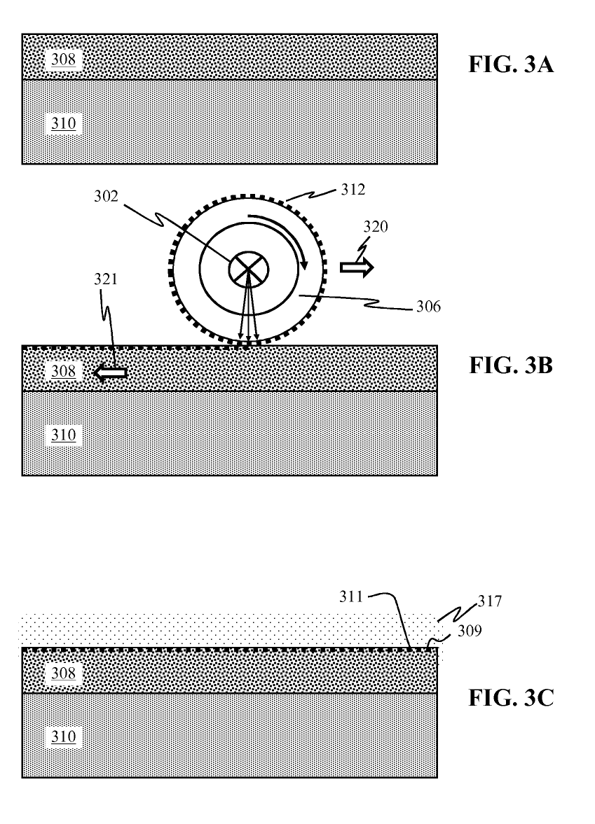

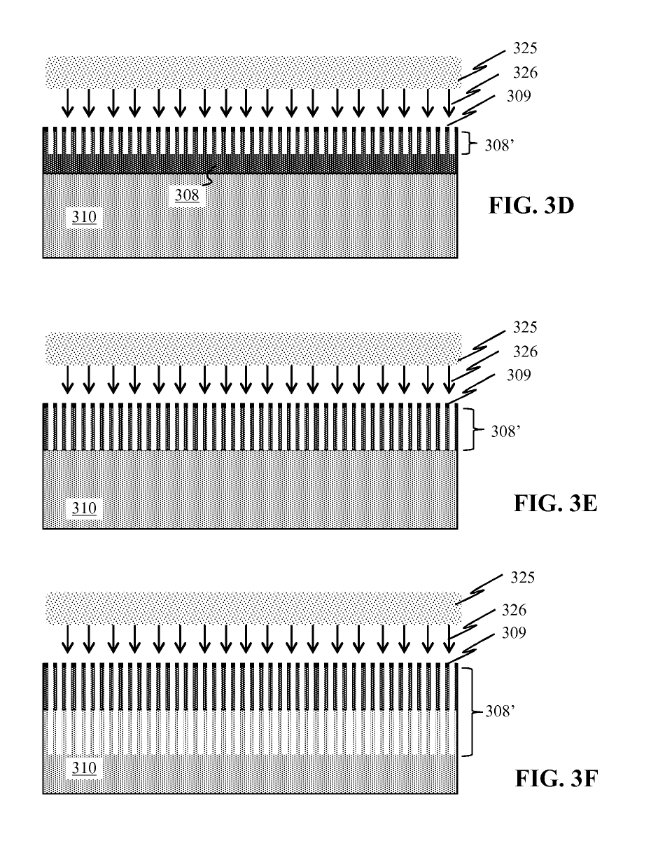

FIGS. 3A-3F illustrate a processing sequence by which a patterned structure may be formed. First, as shown at FIG. 3A, a layer of radiation sensitive material 308 (e.g., a photoresist or similar resist) may be formed on a surface of the substrate 310, which may be a semiconductor, metal, insulator, glass, ceramic or other material. The radiation sensitive material 308 may be a layer of positive or negative photoresist. Generally speaking, a positive resist is for which portions exposed to radiation are rendered soluble in a photoresist developer while unexposed portions remain insoluble to the developer. For a negative resist, the portions exposed to radiation become insoluble to the developer while the unexposed portions can be dissolved by the developer.

The radiation sensitive material 308 may be relatively thin, e.g. from 50 nanometers (nm) to about 10 microns and any and all ranges therebetween, more preferably from about 100 nm to 2 microns and any and all ranges therebetween.

By way of example, and not by way of limitation, a radiation sensitive material 308 may be deposited onto a surface of the substrate 310 by spinning, spraying, dipping, roll-coating, etc. In some implementations, once the radiation sensitive material 308 has been deposited, the radiation sensitive material 308 may optionally be soft-baked. Soft-baking may be performed in order to drive away the solvent from the deposited radiation sensitive material 308, to improve the adhesion of the resist to the substrate 310; and to reduce shear stresses that may have been introduced during the deposition of the radiation sensitive material 308. By way of example and not by way of limitation, soft baking may be performed using one of several types of ovens (e.g., convection or a hot plate) at a temperature of approximately 100° C. By way of example, and not by way of limitation, the soft bake may take place at a temperature of about 80-120° C. for a period of time ranging from about 30 seconds to about one minute.

Next, as shown in FIG. 3B, rolling mask lithography is performed to expose selected portions of the radiation sensitive layer 308 to a radiation pattern that leaves the selected portions of a top surface of the radiation sensitive layer 308 resistant to development by a developer and non-selected portions susceptible to development by the developer. A “rolling mask” may include a glass (or quartz) frame in the shape of hollow cylinder 306. A light source 302 is located inside the cylinder 306. A nanopattern 312 may be formed on an outside (or an inside) of the cylinder 306. The rolling mask is brought into contact with the radiation sensitive layer 308. The cylinder rolls with respect to the substrate 310. Such rolling may be implemented by translating the cylinder with respect to the substrate 310 as the cylinder rotates and the substrate remains stationary as indicated by arrow 320. Alternatively, the cylinder 306 may rotate while remaining in a fixed position as the substrate 310 translates relative to the cylinder as indicated by arrow 321. Alternatively, the rolling may be accomplished by a combination of rotation of the cylinder 306 in conjunction with appropriate translation of the cylinder and substrate 310 relative to each other. As the cylinder 306 rolls with respect to the substrate 310 radiation 301 from a source 302 (e.g., a UV lamp) inside the cylinder shines on the nanopattern 312 from inside the cylinder. Selected portions of a top surface of the radiation sensitive material 308 are exposed to radiation and other portions are not, thereby transferring the nanopattern to the radiation sensitive layer.

The nanopattern 312 can be designed to implement phase-shift exposure, and in such case is fabricated as an array of nanogrooves, posts or columns, or may contain features of arbitrary shape. Alternatively, nanopattern can be fabricated as an array or pattern of nanometallic islands for plasmonic printing. The nanopattern 312 on the rolling mask can have features ranging in size from about 1 nanometer to about 100 microns, preferably from about 10 nanometers to about 1 micron, more preferably from about 50 nanometers to about 500 nanometers. The rolling mask can be used to print features ranging in size from about 1 nanometer to about 1000 nanometers, preferably about 10 nanometers to about 500 nanometers, more preferably about 50 nanometers to about 200 nanometers.

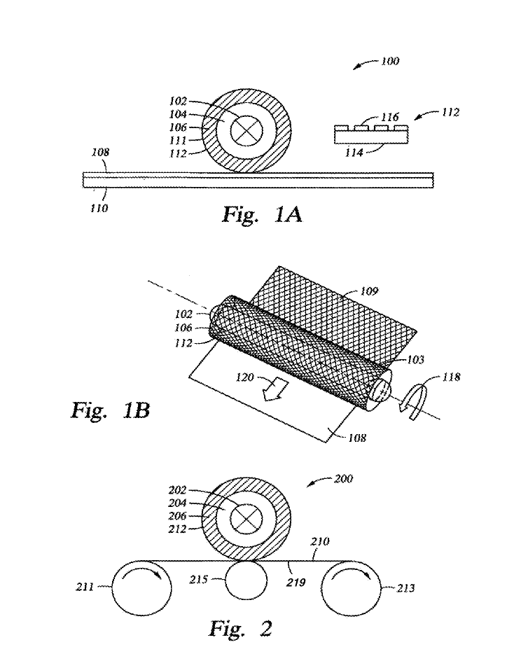

By way of example, and not by way of limitation, sensitive material 308 may be exposed to a pattern of radiation, through the use of rolling mask lithography techniques like those described below with respect to FIGS. 1A-1B and FIG. 2. By way of example, and not by way of limitation, the rolling mask lithography may use a phase shifting mask, a PDMS photomask, or surface plasmon technology.

Following exposure to radiation, the radiation sensitive material 308 may be subjected to a cross-linking process. The nature of the cross-linking process depends partly on the type of radiation sensitive material. By way of example, for many types of photoresist, cross-linking may be accomplished through heating (e.g., baking) the substrate 310 and radiation sensitive material 308 to a sufficient temperature. Other ways of cross-linking include thermal methods, electron beam as well as DUV (248, 193 nm wavelength). The material properties of the radiation sensitive material is such that selected portions 309 (either exposed portions or unexposed portions depending on the type of material) are cross-linked to a significantly lesser degree than other portions 311.

Following exposure to radiation and cross-linking, the selected portions 309 that were less heavily cross-linked may be rendered resistant to an etch process. By way of example, and not by way of limitation, this may be accomplished, e.g., by exposing the radiation sensitive material to an etch resistance agent 317, such as a silylating agent, as shown in FIG. 3C. The etch resistance agent may be a vapor, e.g., an aminosilane compound. As a result of the greater degree of cross-linking in the other portions 311, the permeance of these portions to the resistance agent is reduced compared to the selected portions. The etch resistance agent therefore diffuses more slowly into the other portions 311 and more readily into the selected portions 309. As a result of the greater diffusion of the etch resistance agents, the selected portions 309 react to a greater degree and are rendered more resistant to the etch process than the other portions 311. As such the selected portions 309 may also be referred to as an etch-resistant mask.

As shown in FIG. 3D, the radiation-sensitive material 308 may then be dry etched to a desired depth. The depth of etch may be less than or equal to a thickness of the dry-etchable material 308. By way of example, a plasma 325 may be generated in the vicinity of the substrate 310. A voltage may be applied between the plasma and the substrate 310 or between the plasma and a support on which the substrate rests or is retained. The plasma 325 may be sustained by a DC or AC discharge in a suitable configured processing chamber. It is noted that AC plasma is commonly used for etching dielectric materials. The voltage directs ions 326 from the plasma toward the substrate 310. The ions 326 remove selected portions of the dry-etchable material 308 that are not protected by the etch resistant mask 309 formed by the selected portions that were rendered etch resistant. By way of example, the removal of un-masked portions of the dry-etchable material 308 may be made by direct physical attack (e.g., sputtering), by chemical reaction, or by some combination of physical attack and chemical reaction. The depth of etching may be controlled e.g., by adjusting plasma parameters that control the etch rate and accordingly adjusting the time of etching.

As a result of the etch process, a pattern is transferred from the etch resistant mask 309 to the radiation sensitive layer forming structures 308′, as shown in FIG. 3D. Depending on the patterning process used to pattern the radiation sensitive layer 308 to form the etch-resistant mask 309, features ranging in size from about 10 nm to about 10 microns may be formed in the radiation sensitive material 308. It is noted that by forming the dry-etchable layer 308 on the hard-to-dry-etch substrate 310, the accuracy of etching depth may be drastically improved since it is usually much easier to assure accuracy of thin film deposition than accuracy of etch depth. An example of such an etching process that utilized the hard-to-etch substrate 310 as an etch stop is shown in FIG. 3E.

The width of the structures 308′ may be between about 1 nanometer to about 1000 nanometers, preferably about 10 nanometers to about 500 nanometers, more preferably about 50 nanometers to about 200 nanometers. The structures 308′ may be characterized by an aspect ratio (ratio of width to depth) ranging from about 1:2 to about 1:10, or any range included therein. By way of example, and not by way of limitation, the aspect ratio may be about 1:5. Structures 308′ may also have an aspect ratio that requires that height of the structures 308′ be thicker than the thickness of the dry-etchable layer 308. When this is the case, added height may be added to the structures by etching through the substrate 310, as shown in FIG. 3F. In some cases, this may involve a continuation of the etch process used to etch form the structures 308′. Alternatively, a different etch process may be used after the etch process that forms structures 308′ has etched through to the substrate 310. The etching process used to etch the substrate 310 is dependent on the material that the hard-to-etch substrate 310 is made from. By way of example, and not by way of limitation, if the radiation sensitive layer is Shipley 1805 photoresist and the substrate 310 is made from soda lime glass, an O₂-RIE etch process may be used to etch the radiation sensitive layer 308 to form the structures 308′ and a CHF₃—Ar RIE etch process may thereafter be used to etch the substrate 310. The substrate 310 could be etched away without damaging the structures 308′ by optimizing an anisotropic Reactive Ion Etch process used to etch the substrate. It is further noted, that in some implementations, the structures 308′ may be removed after etching into the substrate 310 using the structures as a mask thereby leaving a corresponding pattern of structures in the substrate 310.

By way of example, the radiation sensitive material 308 may be a traditional novolac/DNQ photoresist. Upon exposure to light (e.g., I-line (365 nm) UV radiation), this type of resist undergoes photodecomposition to yield an indene carboxylic acid. When the resist is then baked in vacuo at high temperatures so that essentially no water is present, the exposed resistant undergoes thermal decomposition to form an unstable ketene. In the absence of water, the ketene reacts with the nucleophilic phenol functionality on the novolac resin. Most PAC molecules contain multiple DNQ groups; so, the unexposed resin may be cross-linked, e.g., by a high temperature bake process. As a result of the cross-linking, the permeance of the unexposed region to gaseous molecules is drastically diminished. The resist may then exposed to the vapor of a reactive aminosilane compound, which permeates into the exposed regions of the photoresist, reacts with free phenolic sites, and incorporates silicon into these regions.

Since the unexposed region is cross-linked, the silylating agent diffuses very slowly into these areas. Therefore the high permeance of the silylating agent into the exposed regions of the film provides a method of selectively incorporating silicon atoms into the resist. The silylated film may then be placed into an oxygen RIE and developed as in the other systems.

In alternative implementations, a p-Hydroxysytrene (P-HOST) polymer may be used within chemically amplified (CA) resists exposed at 248 nm wavelength. Also 193 nm exposure may be used for very thin resist film thickness, e.g., less than 100 nm.

According to additional aspects of the present disclosure, the structures formed in the radiation sensitive material 308 may also optionally be transformed into curved surfaces through the use a multi-level photoresist structure with layers that have different values for their index of refraction. By way of example, and not by way of limitation, one can use a multi-level photoresist structure with each layer having different refractive index, so that the total structure has a gradient of refractive index across the thickness. This way one can change the profile of light distribution in the photoresist to engineer a sloped profile as a result of such exposure/development process.

According to certain aspects of the present disclosure a rotatable mask may be used to pattern the radiation-sensitive material 308. The rotatable mask may be in the form of a cylinder 306. Nanopatterning with a rotatable mask may use techniques that make use of near-field photolithography, where the wavelength of radiation used to image a radiation-sensitive layer on a substrate is 650 nm or less, and where the mask used to pattern the substrate is in contact with the substrate. The near-field photolithography may make use of a phase-shifting mask, or nanoparticles on the surface of a transparent rotating cylinder, or may employ surface plasmon technology, where a metal layer on the rotating cylinder surface comprises nano holes. The detailed description provided below is just a sampling of the possibilities which will be recognized by one skilled in the art upon reading the disclosure herein.

Although the rotating mask used to generate a nanopattern within a layer of radiation-sensitive material 308 may be of any configuration which is beneficial, and a number of these are described below, a hollow cylinder is particularly advantageous in terms of imaged substrate manufacturability at minimal maintenance costs. FIG. 1A shows a cross-sectional view of one example of an apparatus 100 useful in patterning of large areas of substrate material, where a radiation transparent cylinder 106 has a hollow interior 104 in which a radiation source 102 resides. In this embodiment, the exterior surface 111 of the cylinder 106 is patterned with a specific surface relief 112. The cylinder 106 rolls over a radiation sensitive material 108 which overlies a layer of a substrate 110. FIG. 1B shows a top view of the apparatus and substrate illustrated in FIG. 1A, where the radiation sensitive material 108 has been imaged 109 by radiation (not shown) passing through surface relief 112. The cylinder rotates in the direction shown by arrow 118, and radiation from a radiation source 102 passes through the nanopattern 112 present on the exterior surface 103 of rotating cylinder 106 to image the radiation-sensitive layer 108, providing an imaged pattern 109 within the radiation-sensitive layer 108. The radiation-sensitive layer is subsequently developed to provide a nanostructure on the surface of substrate 108. In FIG. 1B, the rotatable cylinder 106 and the radiation-sensitive layer 108 are shown to be independently driven relative to each other. In another embodiment, the radiation-sensitive layer 108 may be kept in dynamic contact with a rotatable cylinder 106 and moved in a direction toward or away from a contact surface of the rotatable cylinder 106 to provide motion to an otherwise static rotatable cylinder 106. In yet another embodiment, the rotatable cylinder 106 may be rotated on a radiation sensitive layer 108 while the radiation sensitive layer 108 is static.

By way of Example, and not by way of limitation, the specific surface relief 112 may be etched into the exterior surface of the transparent rotating cylinder 106. Alternatively, the specific surface relief 112 may be present on a film of polymeric material which is adhered to the exterior surface of rotating cylinder 106. The film of polymeric material may be produced by deposition of a polymeric material onto a mold (master). The master, created on a silicon substrate, for example, may be generated using e-beam direct writing of a pattern into a photoresist present on the silicon substrate. Subsequently the pattern may be etched into the silicon substrate. The pattern on the silicon master mold is then replicated into the polymeric material deposited on the surface of the mold. The polymeric material may be a conformal material that exhibits sufficient rigidity to wear well when used as a contact mask against a substrate but that also can make excellent contact with the radiation-sensitive material on the substrate surface. One example of the conformal materials generally used as a transfer masking material is polydimethylsiloxane (PDMS), which can be cast upon the master mold surface, cured with UV radiation, and peeled from the mold to produce excellent replication of the mold surface.

FIG. 2 shows a cross-sectional view 200 of another embodiment of an apparatus 200 that can be used for patterning large areas of substrate material in conjunction with aspects of the present disclosure. In FIG. 2, the substrate is a film 210 upon which a pattern is imaged by radiation which passes through surface relief 212 on a first (transparent) cylinder 206 while film 210 travels from roll 211 to roll 213. The film 210 may include a layer of dry-etchable material formed on a hard-to-dry etch layer. A second cylinder 215 may be provided on the backside 219 of film 210 to control the contact between the film 210 and the first cylinder 206. The radiation source 202 which is present in the hollow space 204 within transparent cylinder 206 may be a mercury vapor lamp or another radiation source which provides a radiation wavelength of 365 nm or less. The surface relief 212 may be a phase-shift mask, for example, where the mask includes a diffracting surface having a plurality of indentations and protrusions. The protrusions are brought into contact with a surface of a positive photoresist (a radiation-sensitive material), and the surface is exposed to electromagnetic radiation through the phase mask. The phase shift due to radiation passing through indentations as opposed to the protrusions is essentially complete. Minima in intensity of electromagnetic radiation are thereby produced at boundaries between the indentations and protrusions. An elastomeric phase mask conforms well to the surface of the photoresist, and following development of the photoresist, features smaller than 100 nm (e.g., between 10 nm and 100 nm) can be obtained.

Various details of lithographic techniques that use a rotatable mask are described, e.g., in commonly-assigned co-pending U.S. patent application Ser. No. 12/384,219, filed Apr. 1, 2009, the entire disclosures of which are incorporated herein by reference. Various alternatives described therein, among others may be implemented in conjunction with aspects of the present disclosure.

For example in a specialized implementation of a light source of radiation, a flexible organic light emitting diode (OLED) display may be attached around the exterior of the rotatable mask. Light may be emitted toward the substrate from each of the LED pixels in the display. In this implementation the rotatable mask does not need to be transparent. In addition, the particular pattern to be transferred to a radiation-sensitive material on the substrate surface may be selectively generated depending on the application, through control of the light emitted from the OLED. The pattern to be transferred may be changed “on the fly” without the need to shut down the manufacturing line.

According to another aspect, to provide high throughput of pattern transfer to a radiation-sensitive material, and increase the quantity of nanopatterned surface area, it is helpful to move the substrate 210 or the rotatable mask, such as a cylinder 204, against each other. The cylinder 204 may be rotated on the substrate surface 210 when the substrate is static or the substrate 210 is moved relative to the cylinder 204 while the cylinder is static.

It is useful to be able to control the amount of force which occurs at the contact line between the cylinder 204 and the radiation-sensitive material on the surface of the substrate 210 (for example the contact line between an elastomeric nanopatterned film present on the surface of the cylinder and a photoresist on the substrate surface). To control this contact line, the cylinder 204 may be supported by a tensioning device, such as, for example, springs that compensate for the cylinder's weight. The substrate 210 or cylinder 204 (or both) may be moved (e.g., upward and downward) toward each other, so that a spacing between the surfaces is reduced, until contact is made between the cylinder surface 212 and the radiation-sensitive material (the elastomeric nanopatterned film and the photoresist on the substrate surface, for example). The elastomeric nanopatterned film will create a bond with a photoresist via Van-der Walls forces. The substrate position is then moved back (e.g., downward) to a position at which the springs are elongated, but the elastomeric nanopatterned film remains in contact with the photoresist. The substrate 210 may then be moved relative to the cylinder 204, forcing the cylinder to rotate, maintaining a dynamic contact between the elastomeric nanopatterned film and the photoresist on the substrate surface. Alternatively, the cylinder 204 can be rotated and the substrate 210 can be moved independently, but in synchronous motion, which will assure slip-free contact during dynamic exposure.

According to some aspects of the present disclosure, multiple cylinders may be combined into one system and arranged to expose the radiation-sensitive surface of the substrate in a sequential mode, to provide double, triple, and multiple patterning of the substrate surface. This exposure technique can be used to provide higher resolution. The relative positions of the cylinders may be controlled by interferometer and an appropriate computerized control system.

According to another aspect, the exposure dose may affect the lithography, so that an edge lithography (where narrow features can be formed, which corresponds to a shift of phase in a PDMS mask, for example) can be changed to a conventional lithography, and the feature size in an imaged photoresist can be controlled by exposure dose. Such control of the exposure dose is possible by controlling the radiation source power or the rotational speed of the cylinder (exposure time). The feature size produced in the photoresist may also be controlled by changing the wavelength of the exposure radiation, light source, for example.

The relief pattern 212 on the surface cylinders 206 may be oriented by an angle to the direction of substrate movement. This enables pattern formation in different directions against the substrate. Two or more cylinders can be placed in sequence to enable 2D patterns.

According to another aspect, the transparent cylindrical chamber 206 need not be rigid, but may be formed from a flexible material which may be pressurized with an optically transparent gas. The mask may be the cylinder wall or may be a conformal material present on the surface of the cylinder wall. This permits the cylinder 206 to be rolled upon a substrate 210 which is not flat, while making conformal contact with the substrate surface.

According to yet another aspect, instead of a transparent cylinder with nanostructured polymer film laminated on its surface, one can use a free standing nanostructured polymer film, which can be moved from Roll to Roll or in the loop. In that case the pressure between such nanostructured film and a substrate 210 can be controlled by a tension in the film and a relative position of the film and a substrate.

According to an additional aspect, a liquid having a refractive index of greater than one may be used between the cylinder surface 212 and a radiation sensitive (photo sensitive, for example) material present on the substrate surface 210. Water may be used, for example. This enhances the pattern feature's contrast in the photosensitive layer.

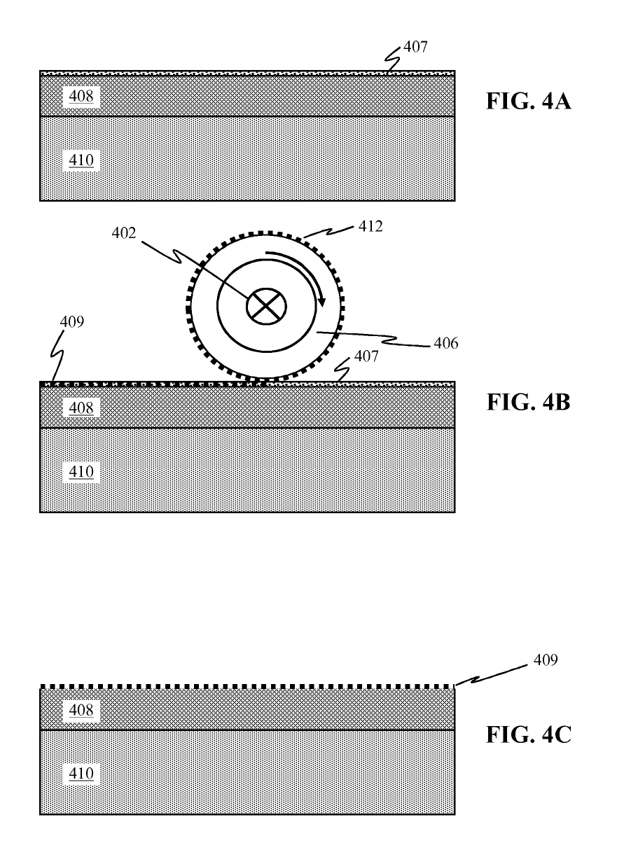

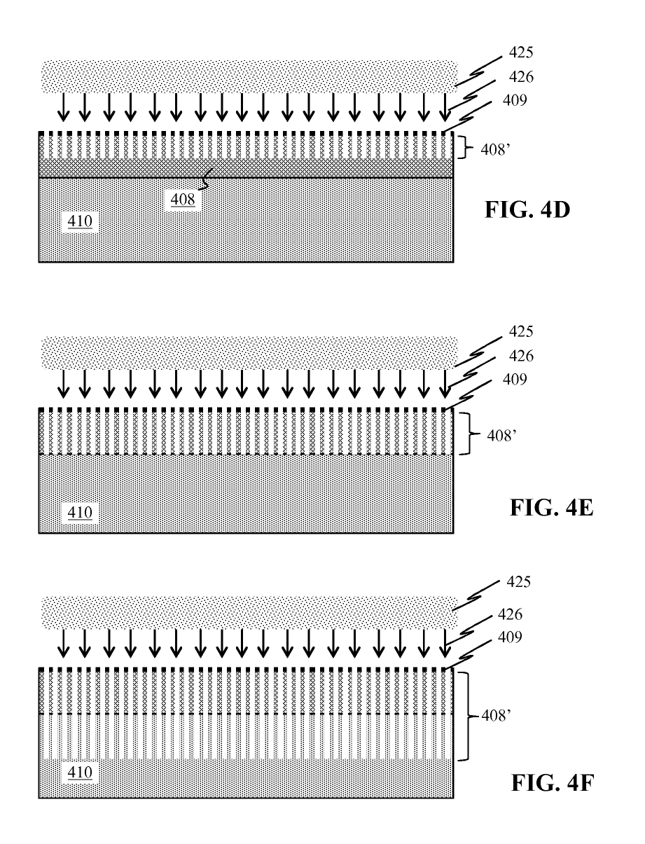

There are a number of alternative patterning processes that may be implemented according to alternative aspects of the disclosure. FIGS. 4A-4F illustrate an alternative processing sequence by which a patterned structure may be formed on a substrate 410. First, as shown in FIG. 4A, a layer of radiation sensitive material 407 (e.g., a photoresist or similar resist) may be formed over a polymer layer 408 that is formed on the substrate 410. The polymer layer 408 need not be radiation sensitive, although it could be. The polymer layer 408 may be formed separate from the radiation sensitive material 407. By way of example, the polymer layer 408 may be formed by depositing a coating of polymer precursor on the substrate 410 and then cross-linking the precursor, e.g., by application of heat or electromagnetic radiation depending on the type of precursor.

The polymer layer 408 may be relatively thin, e.g., from 50 nanometers (nm) to about 10 microns and any and all ranges therebetween, more preferably from about 100 nm to 2 microns and any and all ranges therebetween. The radiation sensitive layer 407 may be relatively thin compared to the polymer layer 408.

Next, as shown in FIG. 4B, rolling mask lithography is performed to expose selected portions of the radiation sensitive layer 407 to a radiation pattern that leaves the selected portions of a top surface of the radiation sensitive layer 407 resistant to development by a developer and non-selected portions susceptible to development by the developer. The “rolling mask” may include a transparent hollow cylinder 406 with a light source 402 located inside the cylinder. A nanopattern 412 may be formed on an outside (or an inside) of the cylinder 406. The nanopattern 412 may be designed to implement phase-shift exposure, and in such case is fabricated as an array of nanogrooves, posts or columns, or may contain features of arbitrary shape. Alternatively, the nanopattern 412 can be fabricated as an array or pattern of nanometallic islands for plasmonic printing. The nanopattern 412 on the rolling mask can have features ranging in size from about 1 nanometer to about 100 microns, preferably from about 10 nanometers to about 1 micron, more preferably from about 50 nanometers to about 500 nanometers. The rolling mask can be used to print features ranging in size from about 1 nanometer to about 1000 nanometers, preferably about 10 nanometers to about 500 nanometers, more preferably about 50 nanometers to about 200 nanometers.

The rolling mask is brought into contact with the radiation sensitive layer 407 and the cylinder rolls with respect to the layer 407 as the radiation sensitive layer is exposed to light from the light source 402 through the nanopattern 412. As a result of exposure, selected portions 409 of the layer 407 are resistant to developing while other portions are not. Portions that are not resistant to developing may be removed by a developing process leaving behind the developed portions as a mask on top of the polymer layer 408 as shown in FIG. 4C.

As shown in FIG. 4D, the polymer layer 408 may be dry etched to a desired depth though openings in the mask formed by the developed portions 409. The depth of etch may be less than or equal to a thickness of the polymer layer 408. Etching may be performed using ions 426 from a plasma 425 generated in the vicinity of the substrate 410. The plasma 325 may be sustained by a DC or AC discharge in a suitable configured processing chamber. A voltage applied between the plasma and the substrate 410 or between the plasma and a support on which the substrate rests or is retained generates an electric field. The electric field accelerates the ions 426 from the plasma 425 toward the substrate 410. The ions 426 remove selected portions of the polymer material 408 that are not protected by the developed portions 409.

As a result of the etch process, a pattern is transferred from the mask 409 to the polymer layer forming structures 408′, as shown in FIG. 4D. The size of the structures 408′ depends on the patterning process used to pattern the radiation sensitive layer 408. Etching may stop at the surface of the substrate 410 as shown in FIG. 4E. Alternatively the substrate 410 may be etched using the same or a different etch process.

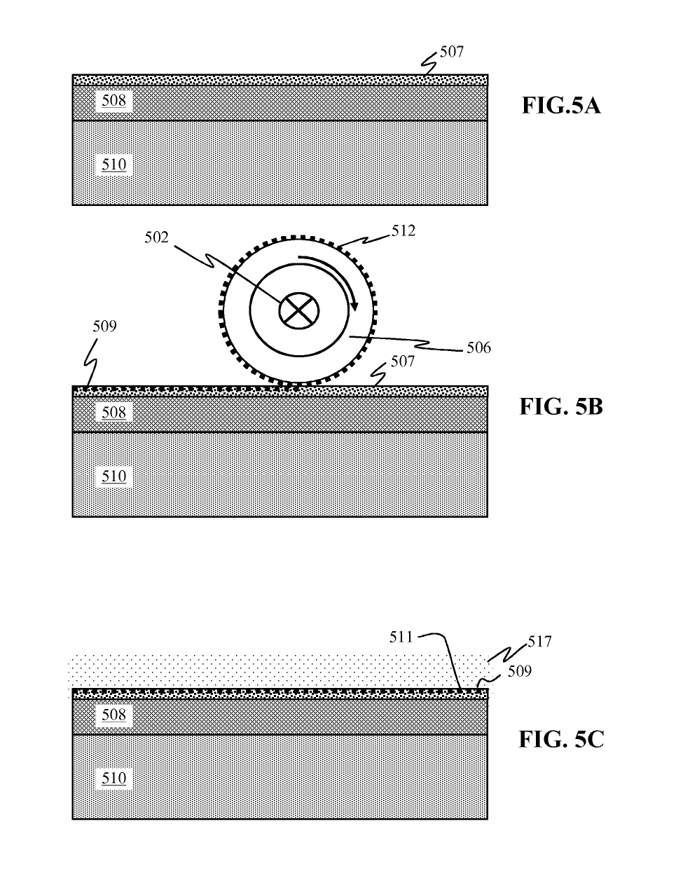

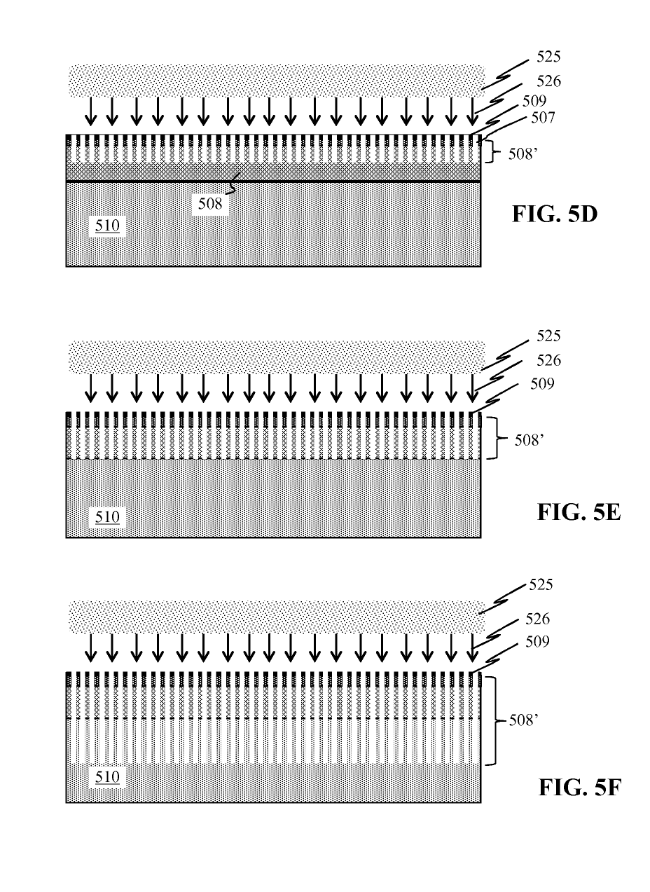

FIGS. 5A-5F illustrate another alternative processing sequence by which a patterned structure may be formed. As shown at FIG. 5A, a layer of radiation sensitive material 507 (e.g., a photoresist or similar resist) may be formed on a surface of a polymer layer 508 that lies on a surface of a substrate 510, e.g., a semiconductor, metal, insulator, glass, ceramic or other material.

Next, as shown in FIG. 5B, rolling mask lithography is performed to expose selected portions of the radiation sensitive layer 507 to a radiation pattern that leaves the selected portions of a top surface of the radiation sensitive layer 507 resistant to development by a developer and non-selected portions susceptible to development by the developer. The “rolling mask” may include a light source 502 inside a transparent hollow cylinder 506 having a nanopattern 512 formed on an outside (or an inside) surface of the cylinder. The nanopattern 512 may be designed to implement phase-shift exposure, and in such case is fabricated as an array of nanogrooves, posts or columns, or may contain features of arbitrary shape. Alternatively, the nanopattern 512 can be fabricated as an array or pattern of nanometallic islands for plasmonic printing. The nanopattern 512 on the cylinder 506 can have features ranging in size from about 1 nanometer to about 100 microns, preferably from about 10 nanometers to about 1 micron, more preferably from about 50 nanometers to about 500 nanometers. The rolling mask can be used to print features ranging in size from about 1 nanometer to about 1000 nanometers, preferably about 10 nanometers to about 500 nanometers, more preferably about 50 nanometers to about 200 nanometers.

By way of example, and not by way of limitation, sensitive material 508 may be exposed to a pattern of radiation, through the use of rolling mask lithography techniques like those described below with respect to FIGS. 1A-1B and FIG. 2. By way of example, and not by way of limitation, the rolling mask lithography may use a phase shifting mask, a PDMS photomask, or surface plasmon technology.

Following exposure to radiation, the radiation sensitive material 508 may be subjected to a cross-linking process. The nature of the cross-linking process depends partly on the type of radiation sensitive material. By way of example, for many types of photoresist, cross-linking may be accomplished through heating (e.g., baking) the substrate 510 and radiation sensitive material 508 to a sufficient temperature. The material properties of the radiation sensitive material is such that selected portions 509 (either exposed portions or unexposed portions depending on the type of material) are cross-linked to a significantly lesser degree than other portions 511.

Following exposure to radiation and cross-linking, the selected portions 509 that were less heavily cross-linked may be rendered resistant to an etch process. By way of example, and not by way of limitation, this may be accomplished, e.g., by exposing the radiation sensitive material to an etch resistance agent 517, such as a silylating agent, as shown in FIG. 5C. As noted above, the etch resistance agent 517 diffuses more slowly into the more heavily cross-linked other portions 511 and more readily into the selected portions 509. The selected portions 509 react to a greater degree and are rendered more resistant to the etch process than the other portions 511.

As shown in FIG. 5D, the radiation-sensitive material 507 may be dry etched to a desired depth, e.g., using a plasma 525 may be generated in the vicinity of the substrate 510. Ions 526 from the plasma are directed toward the substrate 510 and remove selected portions of the radiation-sensitive material 507 that are not resistant to the etch process. The depth of etch may be less than or equal to a thickness of the developed radiation sensitive material 508.

As a result of the etch process, a pattern is transferred from the etch resistant mask formed by the selected portions 509 to the radiation sensitive layer 507 forming structures 508′, as shown in FIG. 5D. The etch process may stop at the polymer layer 508. Alternatively, the etch process (or a different subsequent etch process) may proceed to attack the polymer layer 508 through openings in the etch resistant mask 509. In this manner, the pattern of the structures 508′ may be transferred to the polymer layer 508. In some implementations, the substrate 510 may be made of a material that is resistant to the etch process that attacks the polymer layer 508. In such implementations, the substrate 510 may act as an etch stop and the etch process may stop at the surface of the substrate as shown in FIG. 5E.

Alternatively, the substrate 510 may be susceptible to the etch process or to a different subsequent etch process. In this case, the pattern of the structure 508′ may be further transferred to the substrate 510, as shown in FIG. 5F.

According to further additional aspects of the present disclosure, radiation sensitive material used as a masking material may be reflown after it has been developed. Reflowing the developed radiation sensitive material may provide advantages, such as, but not limited to, providing the ability to produce sloped walls in the patterned substrate 210. Sloped walls in the patterned substrate allow for the fabrication of sub-wavelength anti-reflective coatings, self-cleaning coatings, and other advanced nano-structured coatings. Examples of this technique are described in commonly-assigned U.S. patent application Ser. No. 13/553,602, filed on Jul. 19, 2012, the entire contents of which are incorporated herein by reference.

While the above is a complete description of the preferred embodiments of the present invention, it is possible to use various alternatives, modifications, and equivalents. Therefore, the scope of the present invention should be determined not with reference to the above description but should, instead, be determined with reference to the appended claims, along with their full scope of equivalents. The order of recitation of steps in a method is not intended to limit a claim to a particular order of performing the corresponding steps. Any feature, whether preferred or not, may be combined with any other feature, whether preferred or not. In the claims that follow, the indefinite article “A” or “An” refers to a quantity of one or more of the item following the article, except where expressly stated otherwise. The appended claims are not to be interpreted as including means-plus-function limitations, unless such a limitation is explicitly recited in a given claim using the phrase “means for”. Any element in a claim that does not explicitly state “means for” performing a specified function, is not to be interpreted as a “means” or “step” clause as specified in 35 USC §112, ¶6.

1. A method of patterning a substrate, the method comprising:
performing rolling mask lithography to expose selected portions of a top surface of a radiation sensitive layer formed on a substrate to a radiation and leave other portions of the top surface of the radiation sensitive layer unexposed to the radiation, wherein performing rolling mask lithography includes use of phase lithography or plasmonic mask lithography;
subjecting the radiation sensitive layer to a cross-linking process, wherein the cross-linking process cross-links the other portions to a greater degree than the selected portions;
exposing the radiation sensitive layer to etch-resistance agents, wherein the etch resistance agents incorporate into the selected portions to a sufficient degree to render a structure of the selected portions resistant to an etch process, wherein the greater degree of cross-linking of the other portions inhibits incorporation of the etch resistance agents into the other portions leaving the other portions susceptible to etching by the etch process; and
selectively etching the radiation sensitive layer with the etch process using the selected portions that have been rendered resistant to the etch process as an etch mask, wherein an aspect ratio of structures formed by selectively etching the radiation sensitive layer with the etch process is between about 1:2 and about 1:10.

2. The method of claim 1, wherein performing rolling mask lithography includes rolling a rotatable mask over a surface of the radiation sensitive layer while passing radiation through the rotatable mask, whereby an image is created in the radiation sensitive layer, wherein the rotatable mask configured to selectively prevent a portion of the radiation sensitive layer from being exposed to radiation passing through the mask.

3. The method of claim 2, wherein an outer surface of the rotatable mask is configured to deform when in rolling contact with a surface of the radiation sensitive layer.

4. The method of claim 2, wherein the rotatable mask includes features ranging in size from about 10 nm to about 500 nm.

5. The method of claim 2, wherein an outer surface of the rotatable mask is a conformable outer surface, which conforms to the radiation-sensitive layer on the substrate surface.

6. The method of claim 5, wherein the conformable outer surface is a shaped or nanostructured polymeric material.

7. The method of claim 2, wherein the rotatable mask is a phase-shifting mask which causes the radiation to form an interference pattern in the radiation sensitive material.

8. The method of claim 2, wherein the rotatable mask employs surface plasmon behavior.

9. The method of claim 2, wherein the rotatable mask is a cylinder.

10. The method of claim 9, wherein the cylinder has a flexible wall, whereby the cylindrical shape may be deformed upon contact with the radiation sensitive material.

11. The method of claim 9, wherein the mask is a phase shifting mask which is present as a relief on a surface of the transparent cylinder.

12. The method of claim 9, wherein the mask is a phase shifting mask which is present on a layer applied over a surface of the cylinder.

13. The method of claim 9, wherein the substrate is moved in a direction toward or away from a contact surface of the rotatable cylinder during distribution of radiation from the contact surface of the cylinder.

14. The method of claim 9, wherein the cylinder is rotated on the substrate while the substrate is static.

15. The method of claim 2, wherein the rotatable mask and the substrate surface are moved independently and wherein movement of the rotatable mask and the substrate surface are synchronized with each other.

16. The method of claim 1, wherein selectively etching the radiation sensitive layer with the etch process includes etching through portions of the radiation sensitive layer that have not been rendered resistant to the etch process partway to a surface of the substrate

17. The method of claim 1, wherein selectively etching the radiation sensitive layer with the etch process includes etching through portions of the radiation sensitive layer that have not been rendered resistant to the etch process all the way to a surface of the substrate.

18. The method of claim 17, further comprising etching the substrate through openings formed in the radiation sensitive layer by the etch process.

19. (canceled)

20. The method of claim 19, wherein a width of the structures formed by selectively etching the radiation sensitive layer with the etch process is between about 10 nm and about 500 nm.

21. The method of claim 1, wherein the etch-resistance agents are silylating agents.

22. The method of claim 1, wherein the cross-linking process is a heating process.

23. A method of patterning a substrate, the method comprising:
performing rolling mask lithography to expose selected portions of a radiation sensitive layer formed on polymer layer on a substrate to expose selected portions of a top surface of the radiation sensitive layer to a radiation and leave other portions of the top surface of the radiation sensitive layer unexposed to the radiation, wherein performing rolling mask lithography includes use of phase lithography or plasmonic mask lithography;
rendering a structure of the selected portions resistant to an etch process to form a mask; and
selectively etching the polymer layer through the mask with the etch process, wherein an aspect ratio of structures formed by selectively etching the polymer layer with the etch process is between about 1:2 and about 1:10.

24. The method of claim 22, wherein rendering a structure of the selected portions resistant to an etch process to form a mask includes subjecting radiation sensitive layer to a cross-linking process, wherein the cross-linking process cross-links the other portions to a greater degree than the other portions;
exposing the radiation sensitive layer to etch-resistance agents, wherein the etch resistance agents incorporate into the selected portions to a sufficient degree to render a structure of the selected portions resistant to an etch process, wherein the greater degree of cross-linking of the other portions inhibits incorporation of the etch resistance agents into the other portions leaving the other portions susceptible to etching by the etch process.

25. The method of claim 24, wherein the etch-resistance agents are silylating agents.

26. The method of claim 24, wherein the cross-linking process is a heating process.

27. The method of claim 22, wherein rendering a structure of the selected portions resistant to an etch process to form a mask includes subjecting the radiation sensitive layer to a developing process after performing the rolling mask lithography.
